(19) United States
(12) Patent Application Publication
(10) Pub. No.: US 2013/0154683 A1
(43) Pub. Date: Jun. 20, 2013

(54) ELECTRICAL CHARACTERISTIC MEASURING APPARATUS AND METHOD OF SOLAR CELL

(71) Applicants: Yu-Tai Li, Taichung (TW); Ren-Chin Shr, Kaohsiung (TW); Chen-Wei Chen, Changhua (TW); Yu-Hsien Lee, Chiayi (TW); Hung-Sen Wu, Taoyuan (TW); Kuan-Wu Lu, Kaohsiung (TW)

(72) Inventors: Yu-Tai Li, Taichung (TW); Ren-Chin Shr, Kaohsiung (TW); Chen-Wei Chen, Changhua (TW); Yu-Hsien Lee, Chiayi (TW); Hung-Sen Wu, Taoyuan (TW); Kuan-Wu Lu, Kaohsiung (TW)

(21) Appl. No.: 13/368,346

(22) Filed: Feb. 8, 2012

(30) Foreign Application Priority Data
Dec. 14, 2011 (TW) 100144393

(51) Int. Cl. G01R 31/26

(52) U.S. Cl. 324/761.01

(57) ABSTRACT

In one exemplary embodiment, an electrical characteristic measuring apparatus of solar cell comprises a resilient metal attached to a bus bar of a solar cell and a conducting device located at one end of the resilient metal. The resilient metal has an open via, and the conducting device contacts with the bus bar through the open via. The electrical characteristic measuring apparatus is attached to the bus bar located at a front plane of solar cell. The resilient metal and the conducting device, respectively, connect electrically to a testing device contacted to electrode located at the back plane of solar cell. Thus the resilient metal, the testing device, and the electrode of the back plane form a current measuring loop, and the conducting device, the testing device, and the electrode of the back plane form a voltage measuring loop.

### CROSS-REFERENCE TO RELATED APPLICATION

The present application is based on, and claims priority from, Taiwan Application No. 100144393, filed Dec. 14, 2011, the disclosure of which is hereby incorporated by reference herein in its entirety.

### TECHNICAL FIELD

The disclosure generally relates to electrical characteristic measuring apparatus and method of solar cell.

### BACKGROUND

Usually measuring method of single polysilicon solar cell utilizes a row of 8 to 16 spring pins side by side to measure current. The measuring method needs to consider uniformity of current distribution and current load that a single spring pin can withstand. For each spring pin with length of about 1-2 cm moving on the same plane and the line, a long piece of metal is set on the upper part of each spring pin, used to fix the spring pin. However, in performing actual measurement process, this metal induces a degree of shading around the conductive lines of solar cell, thus affects the accuracy of measurement results, and furthermore results in calculation error of generating power, which accumulates losses considerably for battery product charges with generating power.

In most cases of using row of pin to ensure that the spring pin contacts the surface of measure sample, generally a pneumatic cylinder coupled with the spring pin to control contact force between the spring pin and the surface of measure sample. In practical operation, because of small contact area (about 100 um) of the spring pin and the measure sample, and instability of the pneumatic cylinder output force, thus easily puts too much pressure on the measure sample, increases rupture risk of the measure sample. Furthermore, man power is needed to ensure keeping height of each spring pin side by side designed at the best measuring height position, in order to provide measurement accuracy. Such way of confirmation by man power, is extremely inconvenient to use after a number of operation.

A patent literature discloses a method of measuring solar cells, this method uses a probe and a coupling line as voltage measurement end, and uses multi probes for current measurement with small electrode wire coupled to each other. This method performs measurement by multi-point contact.

Another patent literature provides a connection method for measuring current-voltage characteristic curve. This technique uses two rows of resilient pressure slices to contact with electrode of solar cell, and through an external computer to control measurement system. This technology uses design of two rows of pin, with a row of spring to control contacting electrode, and with a horizontal metal piece to fix this spring

Yet another patent literature reveals connection and fixing method for measuring battery characteristics. This technique uses two probes on upper and lower sides as electrode contact and clamping of solar cell, when probes move down the probe with resilient and sensing has a signal generated due to loop connection. This technology utilizes multi-point measurement.

### SUMMARY

The exemplary embodiments of the present disclosure may provide electrical characteristic measuring apparatus and method of solar cell.

According to one exemplary embodiment of the present disclosure, there is provided an electrical characteristic measuring apparatus of solar cell, comprising a resilient metal attached to a bus bar of a solar cell, the resilient metal having an open via; and a conducting device located at one end of the resilient metal, the conducting device contacts with the bus bar through the open via.

According to another exemplary embodiment of the present disclosure, there is provided an electrical characteristic measuring method of solar cell, comprising:

attaching a resilient metal of an electrical characteristic measuring apparatus to a bus bar of a solar cell; one end of a conducting device contacts with the bus bar through an open via of the resilient metal; and a testing device contacted to an electrode located at a back plane of the solar cell connects electrically to the resilient metal and the conducting device, respectively.

The foregoing and other features and aspects of the disclosure will become better understood from a careful reading of a detailed description provided herein below with appropriate reference to the accompanying drawings.

### BRIEF DESCRIPTION OF THE DRAWINGS

FIG. 1 shows an electrical characteristic measuring apparatus of solar cell, according to an exemplary embodiment.

FIG. 2 is a schematic view illustrating how to measure current and voltage of a solar cell by using electrical characteristic measuring apparatus, according to an exemplary embodiment.

FIG. 3 shows a cross-section view for corresponding locations of the resilient metal, the conducting device, and the solar cell in FIG. 2, according to an exemplary embodiment.

FIG. 4 is a schematic view illustrating corresponding locations of the resilient metal and the bus bar, according to an exemplary embodiment.

FIG. 5 is a schematic view illustrating an electrical characteristic measuring apparatus of solar cell having fixed devices, according to an exemplary embodiment.

FIG. 6A to FIG. 6D are schematic views for a variety of settings of the open via on the resilient metal, according to an exemplary embodiment.

FIG. 7 shows an electrical characteristic measuring method of solar cell, according to an exemplary embodiment.

### DETAILED DESCRIPTION OF DISCLOSED EMBODIMENTS

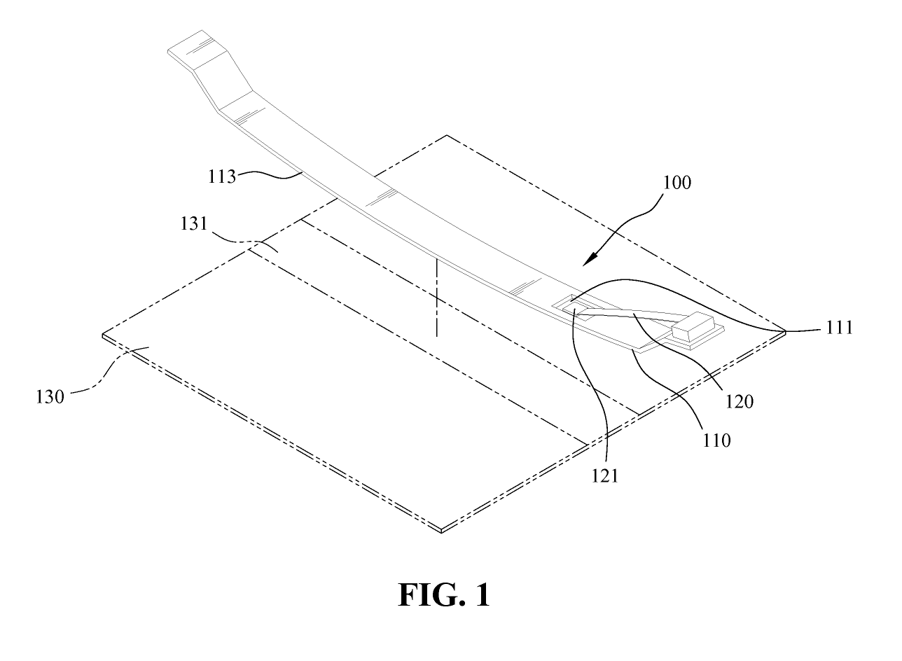

FIG. 1 shows an electrical characteristic measuring apparatus of solar cell, according to an exemplary embodiment. As shown in FIG. 1, the electrical characteristic measuring apparatus 100 includes a resilient metal 110 and a conducting device 120. The resilient metal 110 has an open via 111. The conducting device 120 is located at one end of the resilient metal 110. One measuring end 121 of the conducting device 120 contacts with a bus bar 131 of a solar cell 130 through the open via 111. The resilient metal 110 has a contact surface with curvature 113. In an exemplary embodiment, when the resilient metal 110 is attached to the contact surface with curvature 131 of the solar cell 130, the contact surface with curvature 113 forms a flat surface, and is attached to the bus bar 131.

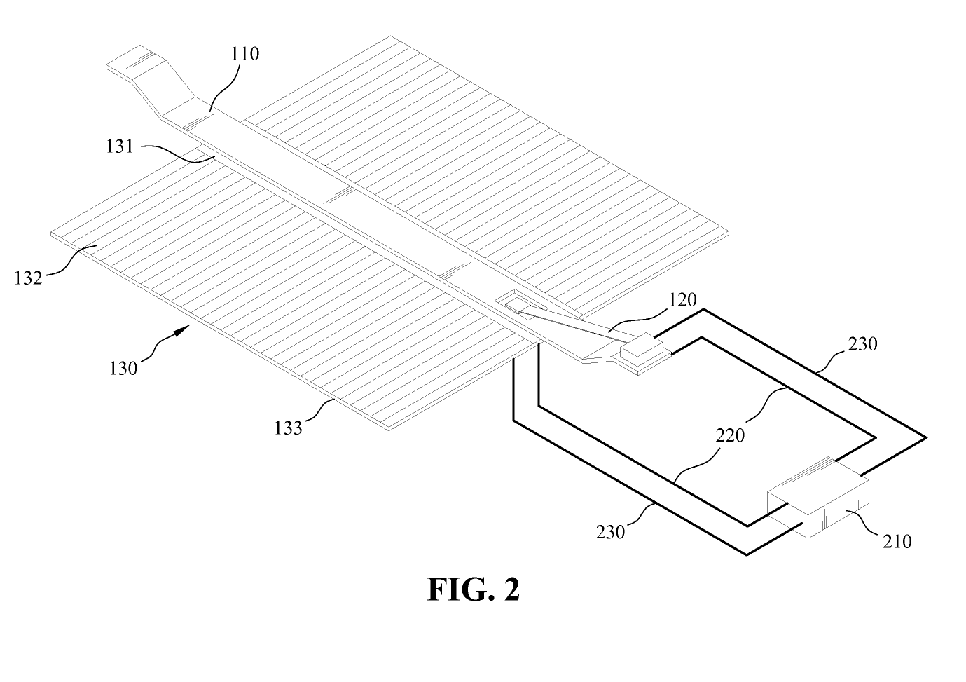

FIG. 2 is a schematic view illustrating how to measure current and voltage of a solar cell by using electrical characteristic measuring apparatus, according to an exemplary embodiment. Referring to FIG. 2, the electrical characteristic measuring apparatus 100 is attached to the bus bar 131 located at the front plane 132 of the solar cell 130, and connects electrically to a testing device 210 contacted to electrode located at the back plane 133 of the solar cell 130. The resilient metal 110, the testing device 130, and the electrode located at the back plane 133 (figure not shown) form a current measuring loop 220. The conducting device 120, the testing device 210, and the electrode located at the back plane 133 (figure not shown) form a voltage measuring loop 230. Since uses only resilient metal 110 for measuring current or voltage of solar cells 130, provides a complete non-shadowing measurement environment, thus increases the accuracy of measurement.

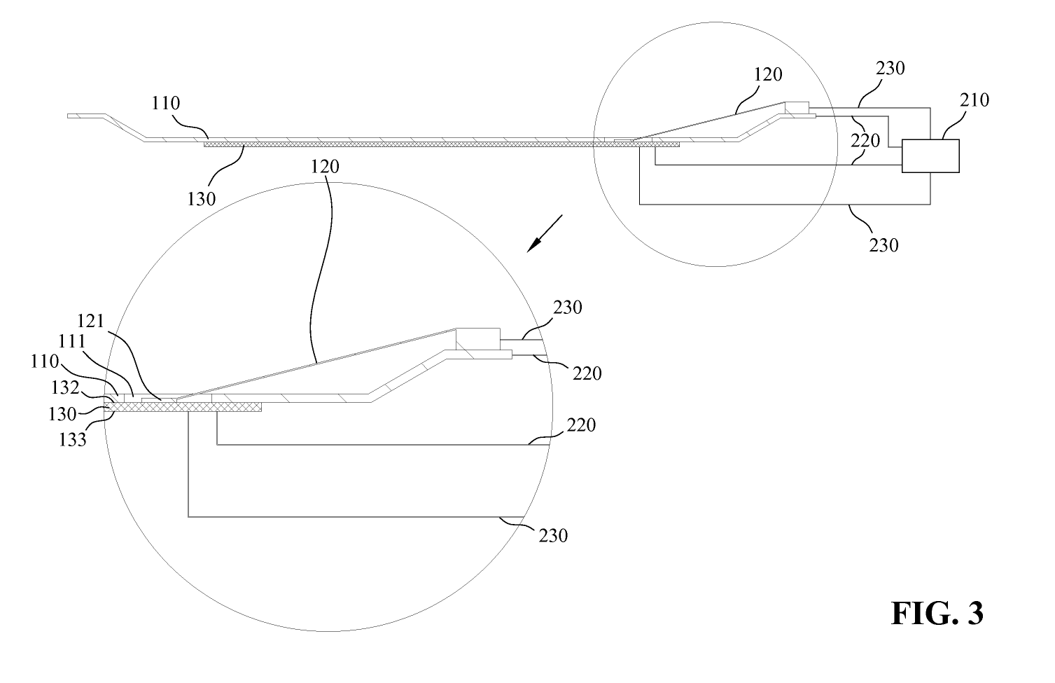

Accordingly, FIG. 3 shows a cross-section view for corresponding locations of the resilient metal, the conducting device, and the solar cell in FIG. 2, according to an exemplary embodiment. As shown in FIG. 3, the electrical characteristic measuring device 100 is attached to the front plane 132 of the solar cell 130, the resilient metal 110 is attached to the front plane 132 of the solar cell 130, also the resilient metal 110 is connected electrically to a testing device 210 attached to the back plane 133 of the solar cell 130. One measuring end 121 of the conducting device 120 contacts with the bus bar 131 located at the front plane 132 of the solar cell 130(figure not shown), also the conducting device 120 is connected electrically to a testing device 210 attached to the back plane 133 of the solar cell 130. This provides minimum required contact area for voltage measurement, thus increases accuracy of measurement results. The thickness of the resilient metal 110 and the conducting device 120 are both less than 2 mm, so when the solar cell 130 exposes light with any angle, the resilient metal 110 would neither produce shadowing effect to the solar cell 130, thereby increases the accuracy of measurement. The resilient metal 110 is insulated from the conducting device 120, thus helps reducing inaccuracy of measurement.

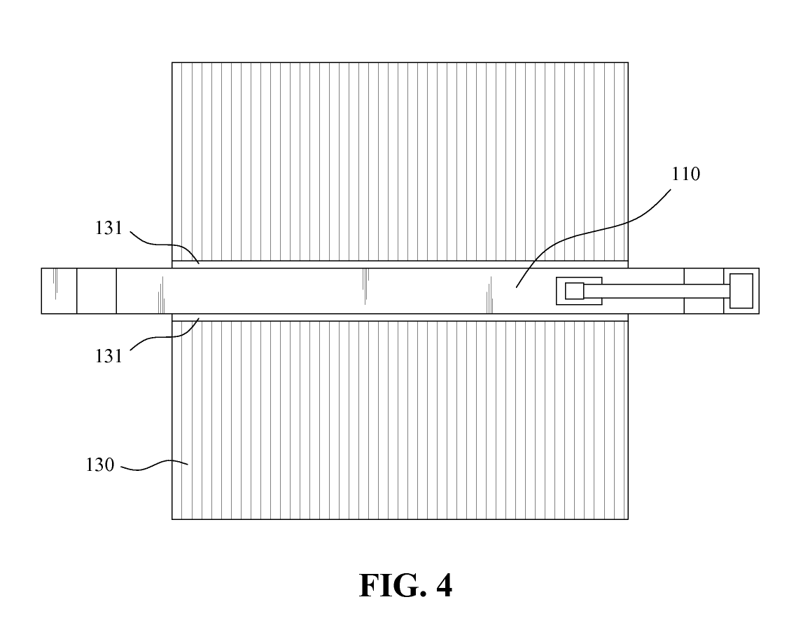

FIG. 4 is a schematic view illustrating corresponding locations of the resilient metal and the bus bar, according to an exemplary embodiment. As shown in FIG. 4, the width of the resilient metal 110 is less than the width of the bus bar 131 on the solar cell 130. This provides maximum required area for current measurement, thus increases accuracy of measurement results.

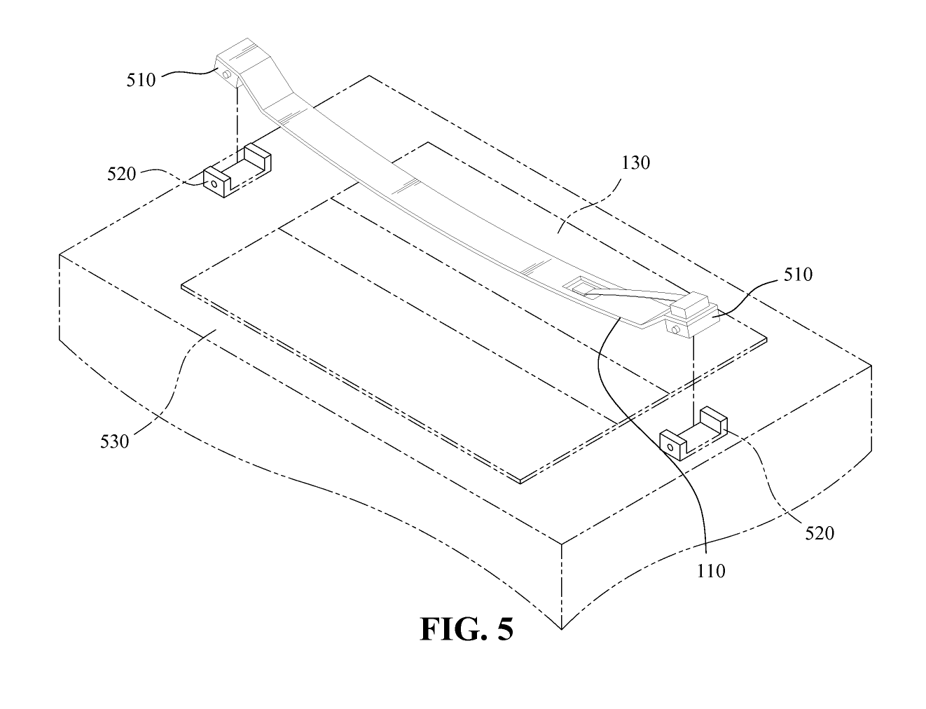

FIG. 5 is a schematic view illustrating an electrical characteristic measuring apparatus of solar cell having fixed devices, according to an exemplary embodiment. As shown in FIG. 5, the electrical characteristic measuring apparatus 100 may include a first fixed device 510 and a second fixed device 520. The first fixed device 510 is located at both ends of the resilient metal 110, the second fixed device 520 can combines or dismantles with the first fixed device 510. The second fixed device 520 is assembled on a platform 530 having a solar cell 130, the platform 530 is such as a test platform or a working platform. Wherein the first and the second devices 510, 520 may be magnetic components, and are mutually adsorbed, the first and the second devices 510, 520 may also be devices having elastic spring, may be assembled at any time, thus increases convenience of the electrical characteristic measuring apparatus 100.

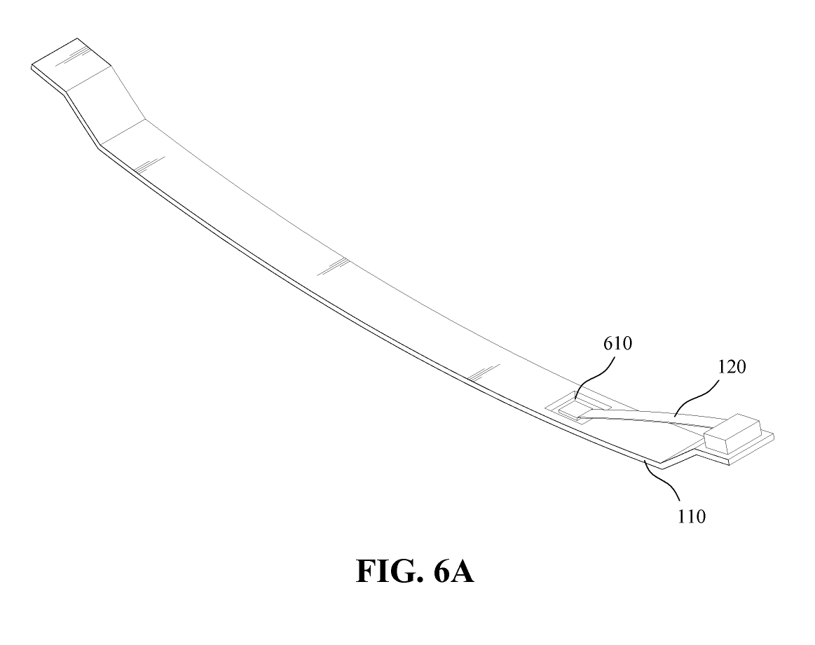

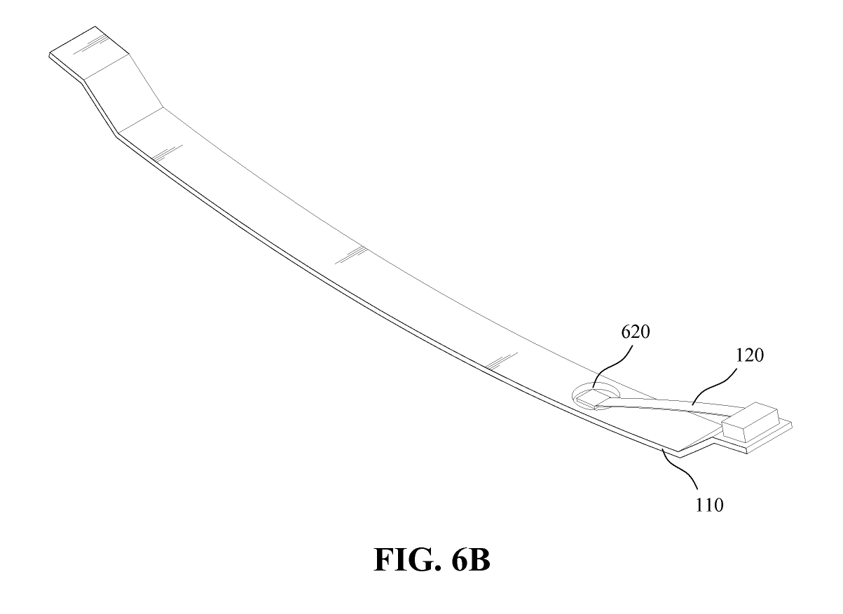

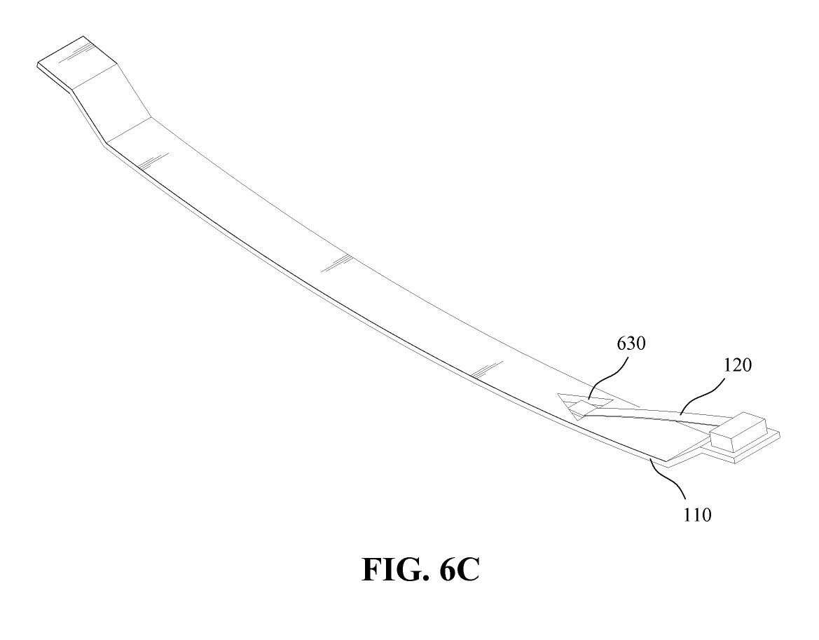

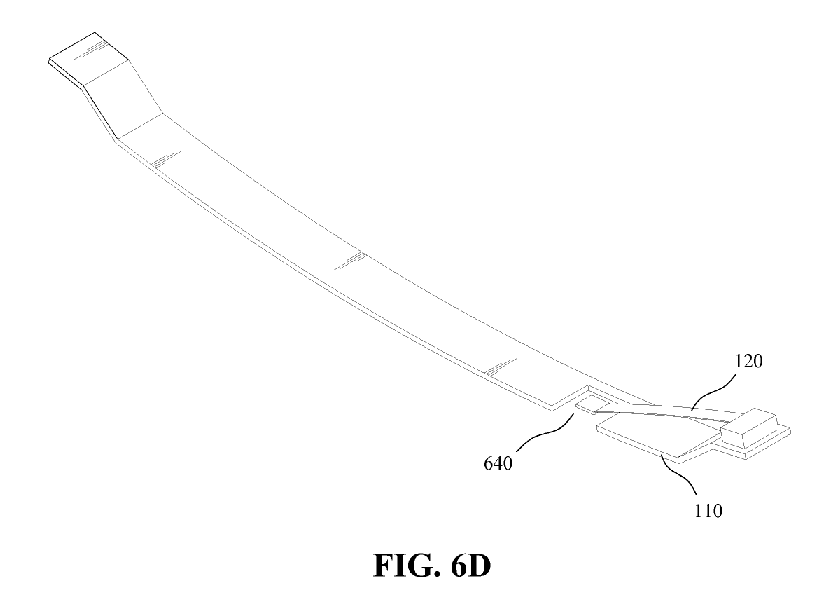

The above description for the open via of the resilient metal is an exemplary embodiment of the open via with single location and single shape. In practical application, the location and the shape of the open via may change according to different needs, and may be set up at any location on the resilient metal. So the following provides a variety of different settings for open via. FIG. 6A to FIG. 6D are schematic views for a variety of settings of the open via on the resilient metal, according to an exemplary embodiment. As shown in FIG. 6A, the open via 610 is a rectangular. As shown in FIG. 6B, the open via 620 is a circular. As shown in FIG. 6C, the open via 630 is a triangular. As shown in FIG. 6C, the open via 640 is a notch.

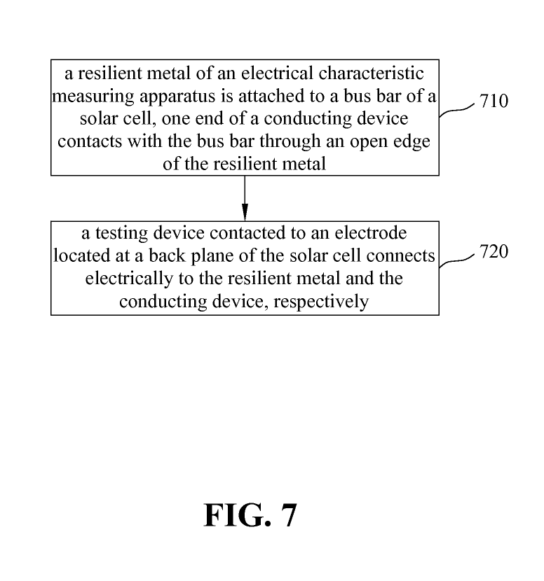

FIG. 7 shows an electrical characteristic measuring method of solar cell, according to an exemplary embodiment. As shown in FIG. 7, this method may comprises:

a resilient metal of an electrical characteristic measuring apparatus is attached to a bus bar of a solar cell, one end of a conducting device contacts with the bus bar through an open via of the resilient metal (as shown in step 710); and a testing device contacted to an electrode located at a back plane of the solar cell connects electrically to the resilient metal and the conducting device, respectively (as shown in step 720).

Therefore, the resilient metal, the testing device, and the electrode of back plane form a current measuring loop. The conducting device, the testing device, and the electrode of back plane form a voltage measuring loop.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An electrical characteristic measuring apparatus of solar cell, comprising:
a resilient metal attached to a bus bar of a solar cell, and said resilient metal having an open via; and
a conducting device located at one end of said resilient metal, and said conducting device contacts with said bus bar through said open via.

2. The electrical characteristic measuring apparatus as claimed in claim 1, wherein said resilient metal has a contact surface with curvature.

3. The electrical characteristic measuring apparatus as claimed in claim 1, wherein a width of said resilient metal is less than that of said bus bar.

4. The electrical characteristic measuring apparatus as claimed in claim 1, wherein said apparatus further includes a first fixed device and a second fixed device, and said first fixed device is located at both ends of said resilient metal and combines or dismantles with said second fixed device.

5. The electrical characteristic measuring apparatus as claimed in claim 1, wherein said open via is assigned at a contact location of said resilient metal and said bus bar.

6. The electrical characteristic measuring apparatus as claimed in claim 1, wherein said open via has a shape of rectangular or circular or triangular.

7. The electrical characteristic measuring apparatus as claimed in claim 1, wherein said open via is a notch.

8. The electrical characteristic measuring apparatus as claimed in claim 1, wherein said resilient metal is insulated with said conducting device.

9. The electrical characteristic measuring apparatus as claimed in claim 1, wherein a current measuring of said solar cell is through said electrical characteristic measuring apparatus attached to the bus bar located at a front plane of said solar cell, and electrically connected to a testing device contacted to an electrode located at a back plane of said solar cell, and said resilient metal, said testing device, and said electrode located at the back plane form a current measuring loop.

10. The electrical characteristic measuring apparatus as claimed in claim 1, wherein a voltage measuring of said solar cell is through said electrical characteristic measuring apparatus attached to the bus bar located at a front plane of said solar cell, and electrically connected to a testing device contacted to an electrode located at a back plane of said solar cell, and said conducting device, said testing device, and said electrode located at the back plane form a voltage measuring loop.

11. An electrical characteristic measuring method of solar cell, comprising:
attaching a resilient metal of an electrical characteristic measuring apparatus to a bus bar located at front plane of a solar cell, and one end of a conducting device being contacted with said bus bar through an open via of said resilient metal; and
a testing device being contacted to an electrode located at a back plane of said solar cell connects electrically to said resilient metal and said conducting device, respectively.

12. The electrical characteristic measuring method as claimed in claim 11, wherein said resilient metal, said testing device, and said electrode located at the back plane form a current measuring loop.

13. The electrical characteristic measuring method as claimed in claim 11, wherein said conducting device, said testing device, and said electrode located at the back plane form a voltage measuring loop.

14. The electrical characteristic measuring method as claimed in claim 11, further comprising:
assigning said open via to be at a contact location of said resilient metal and said bus bar.

15. The electrical characteristic measuring method as claimed in claim 11, further comprising:
insulating said resilient metal with said conducting device.

16. The electrical characteristic measuring method as claimed in claim 11, further comprising:
installing a first fixed device at both ends of said resilient metal to combine or dismantle with a second fixed device.
